(19) United States
(12) Patent Application Publication
(10) Pub. No.: US 2011/0059405 A1
(43) Pub. Date: Mar. 10, 2011

(54) SUBSTRATE PROCESSING METHOD

(76) Inventor: Koutaro SHO, Mie-ken (JP)

(21) Appl. No.: 12/775,342

(22) Filed: May 6, 2010

(30) Foreign Application Priority Data
Sep. 7, 2009 (JP) 2009-205669

(51) Int. Cl. G03F 7/20

(52) U.S. Cl. 430/323; 430/325

(57) ABSTRACT

A substrate processing method, includes: forming a resist film above a substrate; exposing the resist film; developing the resist film using a developing fluid after the exposing of the resist film; cleaning the resist film using a rinsing fluid after the developing of the resist film; and drying the resist film in a processing chamber after the cleaning of the resist film, inside the processing chamber being an atmosphere including an ion, the atmosphere including the ion being caused by introducing a gas including the ion produced externally to the processing chamber into the processing chamber.

### CROSS-REFERENCE TO RELATED APPLICATIONS

This application is based upon and claims the benefit of priority from the prior Japanese Patent Application No. 2009-205669, filed on Sep. 7, 2009; the entire contents of which are incorporated herein by reference.

### BACKGROUND

1. Field

Embodiments of the invention relate generally to a substrate processing method.

2. Background Art

Manufacturing methods of semiconductor devices include many processes to deposit multiple substances as films onto a semiconductor wafer and pattern the films into desired patterns. To pattern the films, generally, a photosensitive substance called a resist is deposited onto the film to be patterned to form a resist film; and exposure of prescribed regions of the resist film is performed. Then, a resist pattern is formed by developing to remove the exposed portions or the unexposed portions of the resist film; and the film to be patterned is patterned by etching using the resist pattern as a mask.

Although ultra-violet light such as KrF excimer lasers and ArF excimer lasers is used as an exposure light source for better throughput, problems occur in which the resist pattern collapses as the semiconductor device is downscaled. Although there have been proposals (for example, JP-A 2007-123399 (Kokai)) to make the resist film thinner by introducing a multilayered resist process to reduce the defects caused by the resist pattern collapse, defects caused by resist pattern collapse have yet to be completely eliminated.

### SUMMARY

According to an aspect of the invention, there is provided a substrate processing method, including: forming a resist film above a substrate; exposing the resist film; developing the resist film using a developing fluid after the exposing of the resist film; cleaning the resist film using a rinsing fluid after the developing of the resist film; and drying the resist film in a processing chamber after the cleaning of the resist film, inside the processing chamber being an atmosphere including an ion, the atmosphere including the ion being caused by introducing a gas including the ion produced externally to the processing chamber into the processing chamber.

According to another aspect of the invention, there is provided a substrate processing method, including: forming a resist film above a substrate; exposing the resist film; developing the resist film using a developing fluid after the exposing of the resist film; cleaning the resist film using a rinsing fluid after the developing of the resist film; and drying the resist film by blowing a gas including an ion onto the cleaned resist film.

### BRIEF DESCRIPTION OF THE DRAWINGS

FIG. 1 is a schematic view illustrating the configuration of a substrate processing apparatus according to an embodiment of the invention;

FIGS. 2A to 2D are schematic cross-sectional views illustrating a method for manufacturing a semiconductor device according to the embodiment of the invention;

FIGS. 3A to 3D are schematic views illustrating a substrate processing method according to the embodiment of the invention;

FIG. 4 is a schematic cross-sectional view illustrating a state of a resist film being charged;

FIG. 5 is a schematic view illustrating a substrate processing method according to another embodiment of the invention; and

FIG. 6 is a schematic view illustrating a substrate processing method according to yet another embodiment of the invention.

### DETAILED DESCRIPTION

Embodiments of the invention will now be described with reference to the drawings.

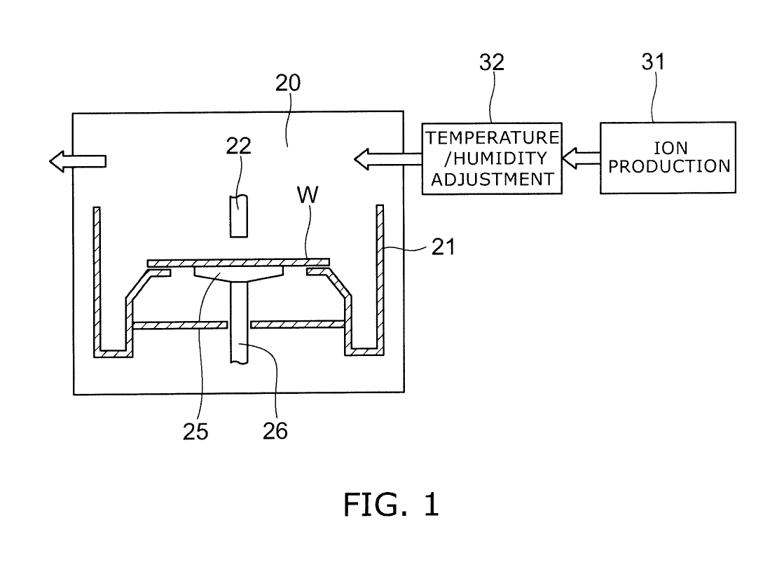

FIG. 1 is a schematic view illustrating the configuration of a substrate processing apparatus according to an embodiment of the invention. The apparatus includes a processing chamber 20 capable of containing a semiconductor wafer W. Developing and rinsing are performed on the semiconductor wafer W in the processing chamber 20.

A spin chuck 25 is provided in the processing chamber 20. The spin chuck 25 is a vacuum chuck. A face (a back face) of the semiconductor wafer W on the side opposite to the processing surface is vacuum-attached to the upper face of the spin chuck 25. The semiconductor wafer W is suction-held substantially horizontally on the spin chuck 25. The spin chuck 25 includes a rotary shaft 26 extending downward. The rotary shaft 26 is linked to a not-illustrated motor. The spin chuck 25 receives a driving force of the motor and is rotatable around the rotary shaft 26.

A nozzle 22 is provided above the spin chuck 25. The nozzle 22 is opposable to the processing surface of the semiconductor wafer W suction-held by the spin chuck 25. The nozzle 22 is connected to a not-illustrated developing fluid and/or rinsing fluid supply mechanism provided externally to the processing chamber 20. A cup 21 surrounds below and around the spin chuck 25. A not-illustrated liquid drainage mechanism is connected to a bottom portion of the cup 21.

An ionizer 31 and a temperature/humidity adjustment apparatus 32 are provided externally to the processing chamber 20.

The ionizer 31 includes, for example, an electro-discharge mechanism and produces ions by exposing a gas to electro-discharge. The ions produced in the ionizer 31 are sent to the temperature/humidity adjustment apparatus 32 with the gas (e.g., air).

The temperature/humidity adjustment apparatus 32 includes a gas transfer chamber, a heating unit, a humidification unit, and the like. The gas including the ions produced in the ionizer 31 is introduced into the gas transfer chamber. The heating unit includes a heater. The temperature in the gas transfer chamber is adjustable by controlling the electrical power supplied to the heater thereof. The humidification unit includes, for example, a mechanism having a heater immersed in water. The moisture evaporation amount in the gas transfer chamber, i.e., the humidity in the gas transfer chamber, is adjustable by controlling the electrical power supplied to the heater thereof. The gas including the ions adjusted to the desired temperature and humidity in the temperature/humidity adjustment apparatus 32 is introduced into the processing chamber 20.

The gas including the ions is introduced into the processing chamber 20 from the ionizer 31 via the temperature/humidity adjustment apparatus 32 by a not-illustrated blowing mechanism and then exhausted from the processing chamber 20 by a not-illustrated exhaust mechanism. Thereby, a gas atmosphere including the ions adjusted to the desired temperature and humidity can be maintained in the processing chamber 20.

A method for manufacturing a semiconductor device according to this embodiment including developing and rinsing of the semiconductor wafer W will now be described.

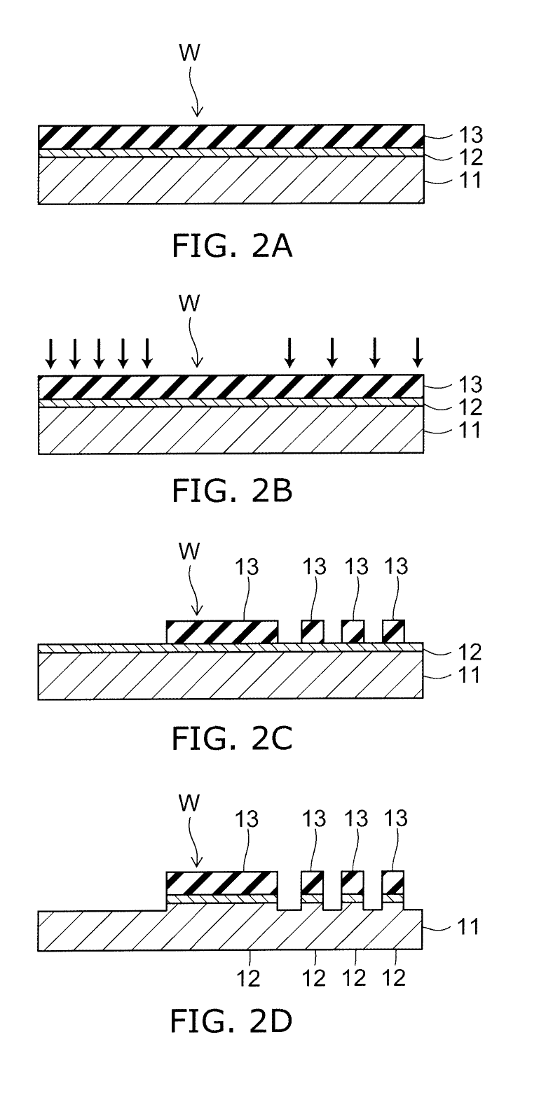

As illustrated in FIG. 2A, an antireflective film 12 is formed on the entire major surface of a substrate 11. A resist film 13 is formed on the antireflective film 12. These components are collectively referred to as the semiconductor wafer W. The substrate 11 is, for example, a silicon substrate. The substrate 11 includes a configuration in which films to be patterned such as an insulating film, a conductive film, a semiconductor film, etc., are formed on a silicon substrate.

Then, selective exposure is performed (FIG. 2B) in a not-illustrated exposure apparatus using a mask (reticle) to transfer the desired latent pattern image onto the resist film 13.

After the exposure, the semiconductor wafer W is transferred into the processing chamber 20 illustrated in FIG. 1 and suction-held by the spin chuck 25. The semiconductor wafer W is suction-held by the spin chuck 25 in a state in which the resist film 13 faces upward.

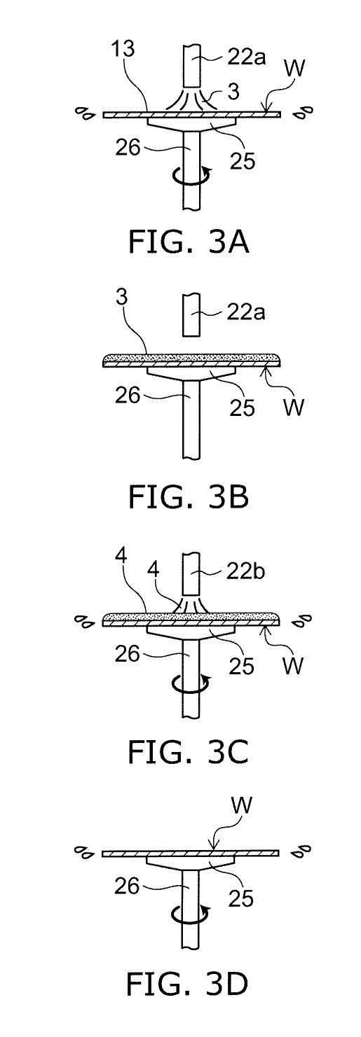

Thereafter, the developing, rinsing, and spin drying processes illustrated in FIGS. 3A to 3D are performed.

First, as illustrated in FIG. 3A, a developing fluid 3 is supplied from a developing fluid nozzle 22a onto the resist film in a state in which the spin chuck 25 holding the semiconductor wafer W is rotated, for example, at several ten to several thousand rpm. The semiconductor wafer W rotates with the spin chuck 25; and the developing fluid 3 supplied substantially in the center of the semiconductor wafer W spreads in the radial direction and spreads over the entire surface of the semiconductor wafer W. The developing fluid 3 includes, for example, TMAH (tetramethylammonium hydroxide).

By stopping the rotation of the spin chuck 25, the developing fluid 3 exists in a state in which the developing fluid 3 swells up on the surface of the semiconductor wafer W due to surface tension as illustrated in FIG. 3B. This state is maintained for the desired period of time.

The resist film 13 is selectively removed by the developing fluid 3 to pattern the resist film 13. In the case where, for example, the resist film 13 is a positive type, the exposed portions are dissolved into the developing fluid 3 and the unexposed portions remain. The state after the developing is illustrated in FIG. 2C. Alternatively, without stopping the rotation of the spin chuck 25, the developing fluid 3 may be continuously supplied in the center of the rotating semiconductor wafer W to develop the resist film 13.

Then, as illustrated in FIG. 3C, a rinsing fluid 4 is supplied from a rinsing fluid nozzle 22b onto the semiconductor wafer W surface in a state in which the spin chuck 25 holding the semiconductor wafer W is rotated at, for example, several thousand rpm. The semiconductor wafer W rotates with the spin chuck 25; and the rinsing fluid 4 supplied substantially onto the center of the semiconductor wafer W spreads in the radial direction and spreads over the entire surface of the semiconductor wafer W. Purified water, for example, may be used as the rinsing fluid 4.

After the cleaning, spin drying is performed to rotate the spin chuck 25 in a state in which the semiconductor wafer W is held as illustrated in FIG. 3D. The spin drying causes the rinsing fluid 4 remaining on the semiconductor wafer W surface to move outward in the radial direction by centrifugal force to remove the rinsing fluid 4 from the semiconductor wafer W.

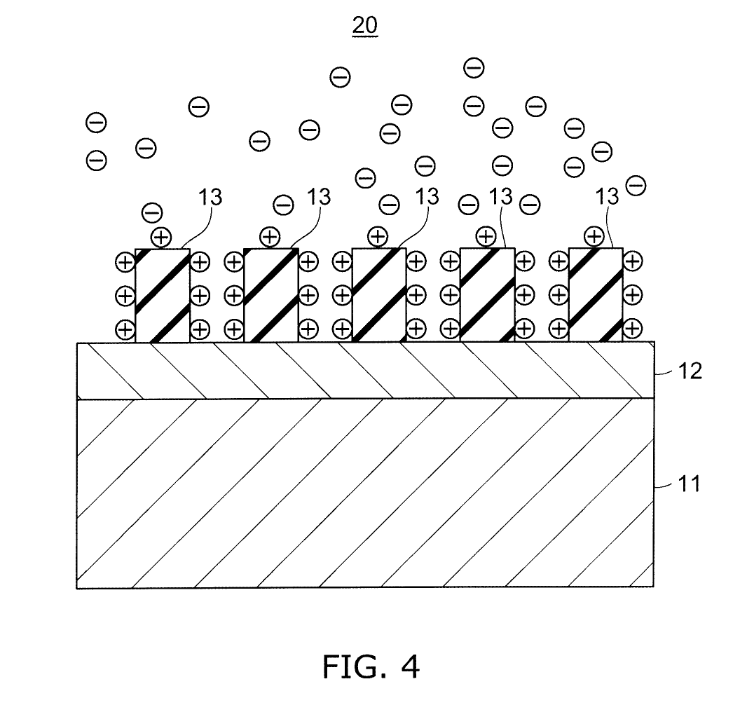

Collapse of the resist pattern had occurred easily during the spin drying. The inventor of the application focused on the charging of the resist film as one cause thereof. There is a tendency for the wafer surface or the resist film 13 to be positively charged as illustrated schematically in FIG. 4 due to the series of wafer processing processes prior to the spin drying process; and it is considered that, in addition to the centrifugal force, effects of the repulsive force between the positive charges between adjacent resist films 13 during the spin drying cause the pattern collapse to occur easily. The semiconductor wafer W also may be easily charged during the spin drying by friction between the semiconductor wafer W and the gas (e.g., air) in the processing chamber 20.

Therefore, in this embodiment, the atmosphere in the processing chamber 20 during the developing, the cleaning, and the spin drying is an ion atmosphere. Specifically, negative ions having a polarity opposite to the charge (the positive charge) of the semiconductor wafer W are produced in the ionizer 31 illustrated in FIG. 1 as described above. A gas (e.g., air) including the negative ions is introduced into the processing chamber 20 via the temperature/humidity adjustment apparatus 32. Thereby, a negative ion atmosphere is provided in the processing chamber 20.

By performing the developing, the cleaning, and the spin drying in the negative ion atmosphere, the charge of the semiconductor wafer W can be neutralized and eliminated or reduced; and the pattern collapse of the resist film 13 during the spin drying can be suppressed. As a result, a resist pattern can be formed without defects over the entire surface of the semiconductor wafer W.

To prevent the pattern collapse during the spin drying due to the semiconductor wafer W being charged, it is sufficient for the ion atmosphere to be provided in the processing chamber 20 at least during the spin drying. However, by maintaining an ion atmosphere in the processing chamber 20 also during the developing and the cleaning (the rinsing), the charging of the semiconductor wafer W during the developing and the cleaning can be eliminated or reduced; and particles occurring in the processing chamber 20 during the developing and the rinsing can be suppressed from adhering to the semiconductor wafer W.

Also, because the developing, the cleaning, and the spin drying are performed continuously in the same processing chamber 20, the processing can be performed efficiently by providing the ion atmosphere in the processing chamber 20 from the developing or cleaning process prior to the spin drying and maintaining the atmosphere through the spin drying.

As a comparative example that provides an ion atmosphere in the processing chamber 20, it may be considered to provide, for example, needle-like electrodes in the processing chamber 20, perform electro-discharge in the processing chamber 20, and produce ions directly in the processing chamber 20. However, in such a case, electrodes are provided in the processing chamber 20 which may cause the structure in the processing chamber 20 to be complex. Also, there is a risk of damage of the semiconductor wafer W due to irregular electro-discharge between the electrodes and the semiconductor wafer W.

Conversely, in this embodiment, the ion atmosphere is provided in the processing chamber 20 by producing ions externally to the processing chamber 20 and introducing the ions into the processing chamber 20. To this end, it is unnecessary to newly provide electrodes in the processing chamber 20; and the structure of a conventional processing chamber, that is, a so-called developer, can be used as-is. Further, electro-discharging is not performed in the processing chamber 20. Therefore, damage of the semiconductor wafer W due to irregular electro-discharge does not occur.

It is desired to control the temperature and the humidity in the processing chamber 20 at the desired values because the temperature and the humidity in the processing chamber 20 affect the film thickness of the resist film 13 and the uniformity in the surface during the developing. However, in the case where electro-discharge is performed in the processing chamber 20, the temperature and the humidity in the processing chamber 20 fluctuates due to the effects of the electro-discharge; and the control thereof is unfortunately difficult.

Conversely, in this embodiment, the temperature and the humidity of the gas (e.g., air) are adjusted to the desired values by the temperature/humidity adjustment apparatus 32 in the state in which the ions are included; and the gas including the ions is then introduced into the processing chamber 20. Therefore, the temperature and the humidity of the atmosphere in the processing chamber 20 have excellent controllability; and the processing quality can be improved.

In this embodiment, an air atmosphere including ions is provided in the processing chamber 20 during the developing and the rinsing. The atmosphere is adjusted to, for example, a temperature of 25° C. and a humidity of 40 to 50%. The atmosphere is adjusted during the spin drying to a higher temperature or a lower humidity than those of the developing and the rinsing.

After patterning the resist film 13 by performing the developing, the cleaning, and the drying described above, the films to be patterned or the substrate 11 are patterned by using the resist pattern as a mask as illustrated in FIG. 2D and performing etching of the antireflective film 12 and the substrate 11 itself or the films to be patterned on the surface layer thereof.

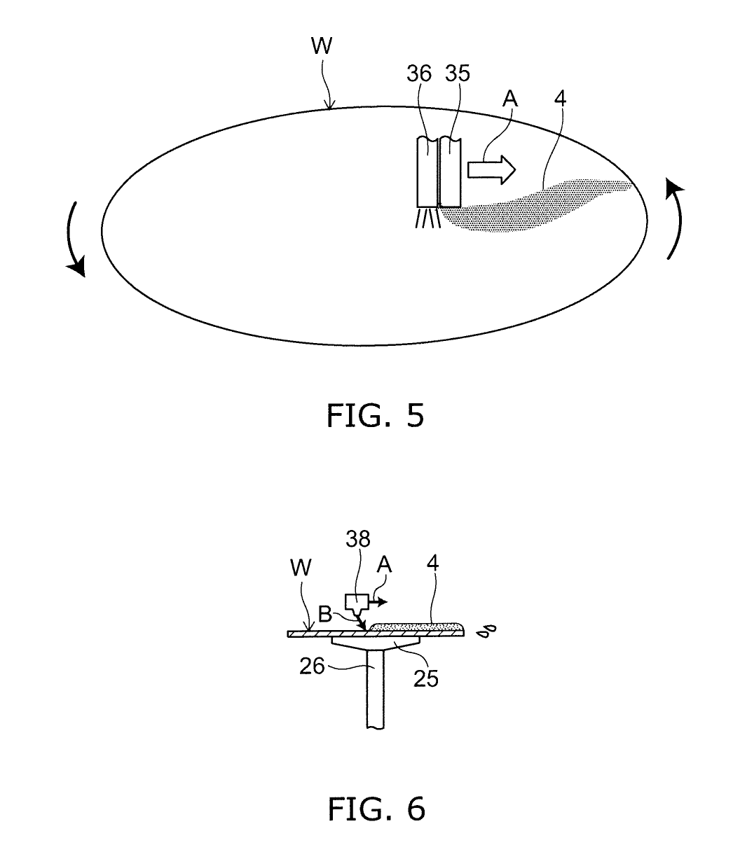

A substrate processing method according to another embodiment of the invention will now be described with reference to FIG. 5. In the embodiment illustrated in FIG. 5, the rinsing process and the drying process are performed simultaneously.

The semiconductor wafer W is rotated in the state of being suction-held by the spin chuck 25 described above. In such a state, the rinsing fluid 4 is supplied from a rinsing fluid nozzle 35 opposing the semiconductor wafer W onto the surface of the semiconductor wafer W; and similarly, a gas (e.g., air or nitrogen gas) including ions is blown from a blow nozzle 36 opposing the semiconductor wafer W onto the surface of the semiconductor wafer W.

Both the rinsing fluid nozzle 35 and the blow nozzle 36 move in a straight line in a surface direction of the semiconductor wafer W. Specifically, the rinsing fluid nozzle 35 supplies the rinsing fluid 4 onto the surface of the semiconductor wafer W while moving in a straight line in a direction A from the center of the semiconductor wafer W in the outer radial direction. Because the semiconductor wafer W is rotating, the rinsing fluid 4 is supplied to the entire surface of the semiconductor wafer W and cleaning is performed for the entire surface of the semiconductor wafer W.

The blow nozzle 36 blows the gas including the ions onto the surface of the semiconductor wafer W while moving in a straight line in the direction A to follow the movement of the rinsing fluid nozzle 35 in the direction A. In other words, the gas including the ions is blown onto the region cleaned with the rinsing fluid 4 to perform the drying of the semiconductor wafer W.

In this embodiment, a gas including negative ions having a polarity opposite to that of the charge (e.g., a positive charge) of the semiconductor wafer W is blown from the blow nozzle 36 onto the semiconductor wafer W. Thereby, the charge of the semiconductor wafer W can be neutralized and eliminated or reduced. Thereby, the pattern collapse of the resist film 13 during the drying can be suppressed; and a resist pattern can be formed without defects over the entire surface of the semiconductor wafer W.

In this embodiment as well, the temperature and the humidity of the processing chamber 20 are adjusted to the desired values during the developing, the rinsing, and the drying. However, the atmosphere thereof may not include ions. The gas including the ions supplied to the blow nozzle 36 is produced externally to the processing chamber 20 and sent to the blow nozzle 36 via a not-illustrated gas supply system. Accordingly, in this embodiment as well, the semiconductor wafer W is not damaged by irregular electro-discharge because electro-discharge is not performed in the processing chamber 20. Further, the temperature and the humidity in the processing chamber 20 do not fluctuate due to effects of electro-discharge; the temperature and the humidity of the atmosphere in the processing chamber 20 have excellent controllability; and the processing quality can be improved.

Next, FIG. 6 illustrates a substrate processing method according to yet another embodiment of the invention.

In this embodiment as well, the gas including the ions is blown onto the semiconductor wafer W to dry the semiconductor wafer W after the rinsing.

The gas including the ions is blown from a blow nozzle 38 toward the semiconductor wafer W. The blow nozzle 38 extends in a direction going into the page surface in FIG. 6. A gas outlet is made in a slit configuration in a lower end portion opposing the semiconductor wafer W. When the blow nozzle 38 moves in the direction A, the gas outlet moves in the direction A above the semiconductor wafer W in a state of opposing the semiconductor wafer W. The gas including the ions, rather than being blown perpendicularly to the processing surface of the semiconductor wafer W, is blown in a direction B obliquely downward from the blow nozzle 38 on the travel direction A side.

By moving the blow nozzle 38 in the direction A while blowing the gas including the ions in the direction B obliquely downward on the travel direction A side, the rinsing fluid 4 on the semiconductor wafer W is pushed by the gas blown from the blow nozzle 38 to flow toward the direction A. At this time, the semiconductor wafer W does not rotate and is stationary.

In the regions of the semiconductor wafer W surface where the blow nozzle 38 passes, the rinsing fluid 4 is pushed to the travel direction A side and removed. The longitudinal direction length of the blow nozzle 38 is not less than the diameter of the semiconductor wafer W. Therefore, by moving the blow nozzle 38 in the direction A from one end of the semiconductor wafer W to the other in the state of opposing the semiconductor wafer W, the rinsing fluid 4 existing on the entire surface of the semiconductor wafer W can be discharged from the semiconductor wafer W.

Here, variation in the fluid level on the both sides of the resist pattern occurs during the drying of the semiconductor wafer W even in the case where the semiconductor wafer W dose not rotate and no centrifugal force is generated. Therefore, it is considered that the pattern collapse easily occurs due to surface tension of fluid.

In this embodiment as well, a gas including negative ions having a polarity opposite to the charge (e.g., a positive charge) of the semiconductor wafer W is blown from the blow nozzle 38 onto the semiconductor wafer W. Thereby, the charge of the semiconductor wafer W can be neutralized and eliminated or reduced. Thereby, the pattern collapse of the resist film 13 during the drying can be suppressed; and a resist pattern can be formed without defects over the entire surface of the semiconductor wafer W.

Further, the gas including the ions supplied to the blow nozzle 38 is produced externally to the processing chamber 20 and sent to the blow nozzle 38 via a not-illustrated gas supply system. Accordingly, in this embodiment as well, the semiconductor wafer W is not damaged by irregular electro-discharge because electro-discharge is not performed in the processing chamber 20. Also, the temperature and the humidity do not fluctuate in the processing chamber 20 due to effects of electro-discharge; the temperature and the humidity of the atmosphere in the processing chamber 20 have excellent controllability; and the processing quality can be improved.

Hereinabove, embodiments of the invention are described with reference to specific examples. However, the invention is not limited thereto. Various modifications are possible based on the technical spirit of the invention.

1. A substrate processing method, comprising:
forming a resist film above a substrate;
exposing the resist film;
developing the resist film using a developing fluid after the exposing of the resist film;
cleaning the resist film using a rinsing fluid after the developing of the resist film; and
drying the resist film in a processing chamber after the cleaning of the resist film,
inside the processing chamber being an atmosphere including an ion,
the atmosphere including the ion being caused by introducing a gas including the ion produced externally to the processing chamber into the processing chamber.

2. The method according to claim 1, wherein the developing, the cleaning and the drying of the resist film are performed continuously in the same processing chamber.

3. The method according to claim 2, wherein the inside of the processing chamber is the atmosphere including the ion also during the cleaning of the resist film.

4. The method according to claim 3, wherein the gas including the ion is introduced in the processing chamber during the developing of the resist film, and the developing, the cleaning and the drying of the resist film are performed while the atmosphere including the ion is maintained in the processing chamber.

5. The method according to claim 1, wherein the gas including the ion in a state of adjusted temperature and humidity is introduced into the processing chamber.

6. The method according to claim 1, wherein the ion has a polarity opposite to a polarity of a charge of the resist film.

7. The method according to claim 1, wherein the ion is a negative ion.

8. The method according to claim 1, wherein the drying is a spin drying including rotating the substrate in the processing chamber.

9. The method according to claim 1, wherein the developing of the resist film includes supplying the developing fluid onto the resist film in a state of the substrate being rotated.

10. The method according to claim 1, wherein the cleaning of the resist film includes supplying the rinsing fluid onto the resist film in a state of the substrate being rotated.

11. The method according to claim 1, further comprising,
etching the substrate using the resist film as a mask after the drying of the resist film.

12. A substrate processing method, comprising:
forming a resist film above a substrate;
exposing the resist film;
developing the resist film using a developing fluid after the exposing of the resist film;
cleaning the resist film using a rinsing fluid after the developing of the resist film; and
drying the resist film by blowing a gas including an ion onto the cleaned resist film.

13. The method according to claim 12, wherein the gas including the ion is blown onto the resist film from a blow nozzle opposing the resist film, the blow nozzle moving in a straight line in a surface direction of the substrate.

14. The method according to claim 13, wherein the gas including the ion is blown onto the resist film from the blow nozzle in a state of the substrate being rotated.

15. The method according to claim 13, wherein:
the resist film is cleaned by supplying the rinsing fluid onto the resist film from a rinsing fluid nozzle opposing the resist film, the rinsing fluid nozzle moving in a straight line in a same direction as the blow nozzle; and
the blow nozzle follows the rinsing fluid nozzle and moves with the rinsing fluid nozzle to blow the gas including the ion onto the resist film having the rinsing fluid supplied.

16. The method according to claim 13, wherein a gas outlet having a slit configuration is formed in a lower end portion of the blow nozzle opposing the resist film.

17. The method according to claim 16, wherein the blow nozzle moves in the straight line while the gas including the ion is blown onto the resist film from the gas outlet having the slit configuration, the gas being blown in a direction obliquely downward on a movement direction side of the blow nozzle.

18. The method according to claim 12, wherein the ion has a polarity opposite to a polarity of a charge of the resist film.

19. The method according to claim 12, wherein the ion is a negative ion.

20. The method according to claim 12, further comprising,
etching the substrate using the resist film as a mask after the drying of the resist film.
